(19) United States
(12) Patent Application Publication
(10) Pub. No.: US 2012/0218826 A1
(43) Pub. Date: Aug. 30, 2012

(54) NON-VOLATILE MEMORY DEVICE AND PROGRAM METHOD THEREOF

(75) Inventor: Min Kyu LEE, Icheon-si (KR)

(73) Assignee: HYNIX SEMICONDUCTOR INC., Icheon-si (KR)

(21) Appl. No.: 13/371,013

(22) Filed: Feb. 10, 2012

(30) Foreign Application Priority Data
Feb. 28, 2011 (KR) 10-2011-0017785

(51) Int. Cl. G11C 16/10

(52) U.S. Cl. 365/185.19

(57) ABSTRACT

A non-volatile memory device and a program method thereof are disclosed. The non-volatile memory device includes a page buffer section connected to the bit lines further connected to memory cells and where the page buffer section is for controlling a potential of the bit lines in response to control signals, and a program controller configured to perform a comparison of a count of a number of program pulses provided to the memory cells with a target number by which a program pulse of the program pulses is to be provided and output the control signals in accordance with the comparison, wherein the target number is set in accordance with a threshold voltage value of the memory cells and a state to be programmed.

### CROSS-REFERENCE TO RELATED APPLICATIONS

This application claims priority under 35 U.S.C. 119(a) to Korean Patent Application No. 10-2011-0017785, filed on Feb. 28, 2011, the contents of which are incorporated herein by reference in its entirety.

### BACKGROUND OF THE INVENTION

1. Field of the Invention

The present invention relates to a non-volatile memory device and a program method thereof, more particularly relates to a non-volatile memory device for enhancing program velocity and a program method thereof.

2. Description of the Related Art

Recently, demand has increased for a non-volatile memory device which enables electrical programming and erasing of data, and does not require a refresh function for periodically rewriting data.

An incremental step pulse programming (hereinafter, referred to as “ISPP”) program method is well-known as a program method of non-volatile memory devices. ISPP involves applying a program pulse which is increased in sequence by a step voltage according to the ISPP program method.

FIG. 1 is a view illustrating a waveform of a program pulse and a verification voltage pulse for describing an ISPP program operation of the non-volatile memory device.

In FIG. 1, the ISPP program operation of the non-volatile memory device repeatedly performs an operation of applying a program pulse and an operation of applying a verification voltage. The ISPP program operation shifts the threshold voltage distribution of a memory cell by applying initial program voltage Vpgm to a word line connected to the memory cell. Subsequently, the ISPP program operation verifies whether or not the threshold voltage distribution of the memory cell shifted to a threshold voltage distribution corresponding to data to be programmed through a method of applying a program verification voltage Vverify. If the threshold voltage distribution of the memory cell shifts to the threshold voltage distribution corresponding to the data, the ISPP program operation applies a supply voltage to a bit line connected to the memory cell so that the threshold voltage distribution of the memory cell is not shifted following an application of the program pulse. If the threshold voltage distribution of the memory cell is lower than that corresponding to the data, the ISPP program operation shifts the threshold voltage distribution of the memory cell by applying new program voltage increased from the initial program voltage Vpgm by a step voltage ΔV to the word line. The ISPP program operation programs the data by shifting the threshold voltage distribution of the memory cell to the threshold voltage distribution corresponding to the data by repeatedly performing the above steps.

As described above, the ISPP program operation repeatedly performs the operation of applying the verification voltage after providing the program pulse, and thus a problem exists in that a total time of the program operation increases due to a time needed for applying the verification voltage.

### SUMMARY OF THE INVENTION

It is a feature of embodiments of the present invention to provide a non-volatile memory for programming simultaneously memory cells by setting a target number by which a program pulse is provided according to a threshold voltage value of the memory cells and a state, and applying a program voltage increased in sequence by the set target number to the memory cell and a method of programming the same. In addition, a program verification operation is skipped by programming simultaneously the programming of the memory cells, and so program operation time reduces.

A non-volatile memory device according to one embodiment of the present invention a page buffer section connected to bit lines further connected to memory cells and where the page buffer section is configured to control a potential of the bit lines in response to control signals; and a program controller configured to perform a comparison of a count of a number of program pulses provided to the memory cells with a target number by which a program pulse of the program pulses is to be provided and output the control signals in accordance with the comparison. Here, the target number is set in accordance with a threshold voltage value of the memory cells and a state to be programmed.

A method of programming a non-volatile memory device according to one embodiment of the present invention includes programming memory cells so that at least one of the memory cells has a threshold voltage higher than a preset threshold voltage; setting a target number by which a program pulse is to be provided to the memory cells by verifying a threshold voltage range of each of the memory cells; applying a program available voltage to a bit line connected to memory cells of which the program pulse is provided a number of program pulses that is identical to or smaller than the target number; and programming the memory cells by increasing the program voltage by a step voltage until the number of program pulses becomes higher than the target number.

A method of programming a non-volatile memory device according to another embodiment of the present invention includes setting a target number by which a program pulse is provided to memory cells according to a target state of each of the memory cells; and providing the program pulse to the memory cells in an increasing sequence. Here, a program inhibition voltage is applied to a bit line connected to a corresponding memory cell if a counting number of the program pulse is higher than a target number of the program pulses to be provided to the memory cells.

As described above, a non-volatile memory device of the present invention programs simultaneously memory cells irrespective of state to be programmed, and so a program verification operation is skipped. As a result, program operation time may reduce.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a view illustrating waveform of a program pulse and a verification voltage pulse for describing an ISPP program operation of a prior art non-volatile memory device;

FIG. 2 is a block diagram illustrating a non-volatile memory device according to an embodiment of the present invention;

FIG. 3 is a block diagram illustrating a program controller depicted in FIG. 2;

FIG. 4 is a view illustrating a waveform of a program pulse for describing a program operation according to an embodiment of the present invention;

FIG. 5A and FIG. 5B are views illustrating a program operation according to an embodiment of the present invention; and

FIG. 6 is a flowchart illustrating a program operation according to an embodiment of the present invention.

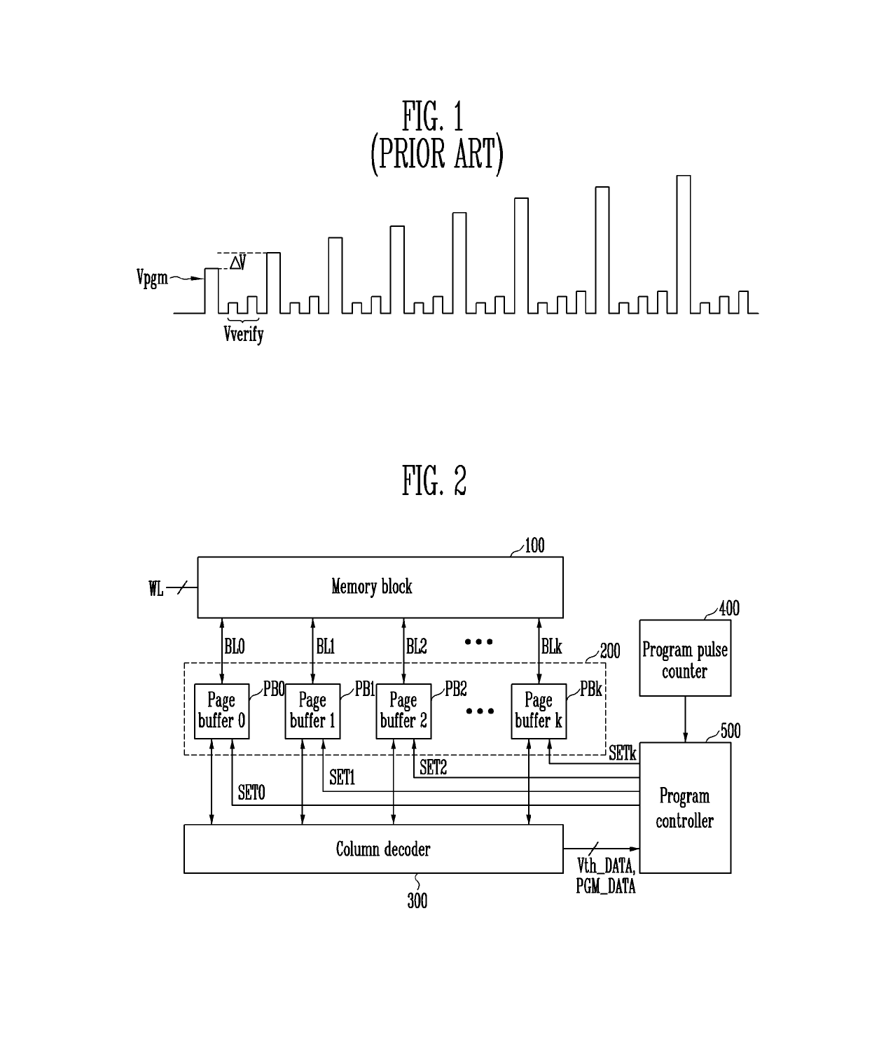

### DESCRIPTION OF SPECIFIC EMBODIMENTS

Hereinafter, embodiments of the present invention will be explained in more detail with reference to the accompanying drawings. Although embodiments have been described with reference to a number of illustrative embodiments thereof, it should be understood that numerous other modifications and embodiments can be devised by those skilled in the art that will fall within the spirit and scope of the principles of this disclosure.

FIG. 2 is a block diagram illustrating a non-volatile memory device according to an embodiment of the present invention.

In FIG. 2, the non-volatile memory device of the present embodiment includes a memory block 100, a page buffer unit (page buffer section) 200, a column decoder 300, a program pulse counter 400 and a program controller 500.

The memory block 100 includes memory cells connected to each of bit lines BL0 to BLk, and memory cells connected to the same bit line are arrayed in serial. The memory cells connected to each of the bit lines BL0 to BLK may be defined in the unit of a page for sharing a word line.

The page buffer section 200 has page buffers PB0 to PBk connected to each of the bit lines BL0 to BLk. Each of the page buffers PB0 to PBk temporarily stores program data to be programmed to a memory cell connected to a corresponding bit line, and each of the page buffers PB0 to PBk controls an electric potential of a corresponding bit line in accordance with the program data. In addition, each of the page buffers PB0 to PBk senses a potential of a corresponding bit line when a verification operation is performed, thereby performing the verification operation associated with programming the data. Each of the page buffers PB0 to PBk senses potential of a corresponding bit line when a read operation is performed, and outputs a threshold voltage distribution value corresponding to the sensed potential to the column decoder 300. Each of the page buffers PB0 to PBk applies a supply voltage which is a program inhibition voltage to a corresponding bit line in response to one of control signals SET0 to SETk outputted from the program controller 500.

The column decoder 300 transmits the program data PGM_DATA inputted through an input/output line IO to the page puffers PB0 to PBk of the page buffer section 200 and the program controller 500 when the program operation is performed. The column decoder 300 receives sensing data Vth_DATA from the page buffers PB0 to PBk during the read operation of threshold voltage, and transmits the received sensing data Vth_DATA to the program controller 500.

The program pulse counter 400 counts program pulses provided to a word line WL of the memory block 100 during the program operation, and outputs to the program controller 500 a counting signal corresponding to a counted number of the program pulses.

The program controller 500 sets a target number by which the program pulse is provided in accordance with the threshold voltage distribution value of the memory cells outputted from the column decoder 300 and the program data of each of the memory cells, the program controller 500 compares the set target number with the counted number of the program pulses in accordance with the counting signal outputted from the program pulse counter 400, and the program controller 500 outputs control signals corresponding to the compared result to the page buffer section 200.

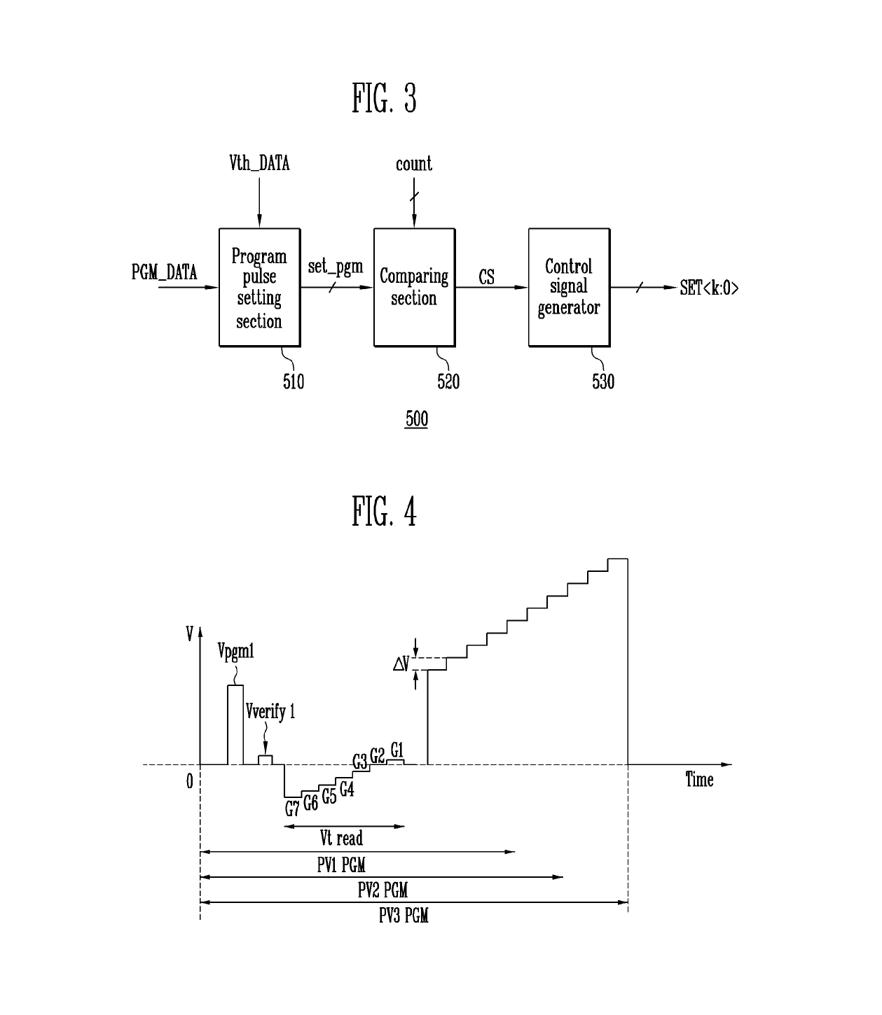

FIG. 3 is a block diagram illustrating the program controller in FIG. 2.

In FIG. 3, the program controller 500 includes a program pulse setting unit (program pulse setting section) 510, a comparing unit (comparing section) 520 and a control signal generator 530.

The program pulse setting section 510 sets and outputs the target number set_pgm in response to the program data PGM_DATA and the sensing data Vth_DATA. The program data PGM_DATA may be transmitted from the column decoder 300. The sensing data Vth_DATA may be transmitted during the read operation.

The comparing section 520 outputs a comparing signal CS in response to the target number set_pgm and the counting signal. The counting signal may be outputted from the program pulse counter 400.

The control signal generator 530 outputs control signals SET<k:0> in response to the comparing signal cs.

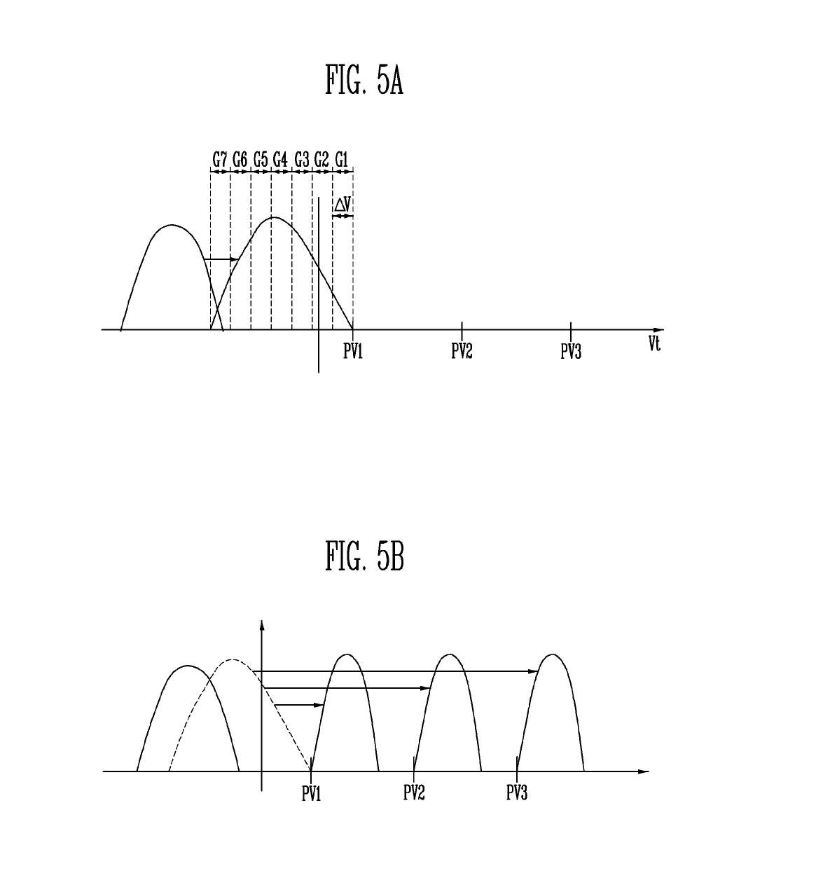

FIG. 4 is a view illustrating waveform of program pulse for describing a program operation according to an embodiment of the present invention.

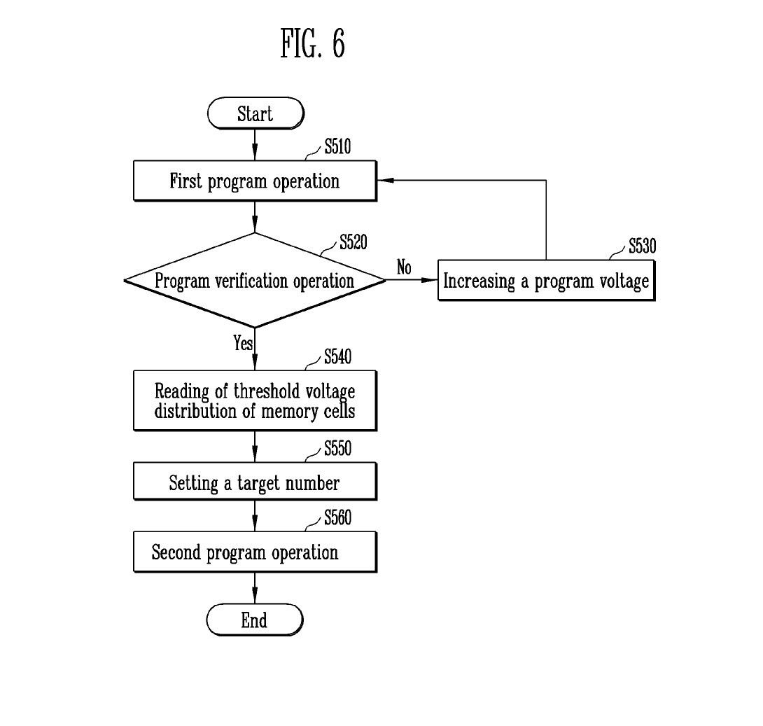

FIG. 5A and FIG. 5B are views illustrating a program operation according to an embodiment of the present invention.

FIG. 6 is a flowchart illustrating a program operation according to an embodiment of the present invention.

A method of programming data according to one embodiment of the present invention will be described in detail with reference to drawings FIG. 2 to FIG. 4.

1) First Program Operation S510

Program data inputted through the input/output line IO is transmitted to one of the page buffers PB0 to PBk by the column decoder 300. Each of the page buffers PB0 to PBk controls an electric potential of a bit line corresponding to the program data. The page buffers PB0 to PBk controls the electric potential of a bit line to supply a voltage which is either a program inhibition voltage or a ground voltage which is a program allowable voltage, where the voltage is supplied in accordance with the transmitted program data. Subsequently, each of the page buffers PB0 to PBk provides a program voltage Vpgm1 to a word line WL shared by memory cells.

In case of storing the program data in the page buffers PB0 to PBk, the program controller 500 receives the program data from the column decoder 300 and stores the received program data.

2) Program Verification Operation S520

Whether a threshold voltage of at least one of the memory cells is higher than a first verification level PV1 may be verified through the program verification operation. More particularly, the bit lines BL0 to BLk are precharged to a high level by using the page buffers PB0 to PBk. A verification voltage Vverify1 is applied to the word line WL. Subsequently, potential change of the bit lines BL0 to BLk is sensed by using the page buffers PB0 to PBk, and the program verification operation passes if a potential level of one or more bit lines is discharged to a low level. However, the program verification operation fails if the threshold voltage of every memory cell is the same as or smaller than the first verification level PV1.

3) Step of Increasing the Program Voltage S530

If it is determined at step S520 that the threshold voltage of every memory cell is the same as or smaller than the first verification level PV1, the program voltage is reset by increasing the program voltage Vpgm1 by a step voltage ΔV. Then, the step S510 and the following step S520 are performed again by using the reset program voltage. Here, the step voltage ΔV is desirable to have a voltage of 0.3V to 1.0V.

4) Operation of Reading Threshold Voltage Distribution of the Memory Cell S540

If it is determined at step S520 that the threshold voltage of at least one memory cell is higher than the first verification level PV1, a potential range of the threshold voltage of each of the memory cells is verified by reading the threshold voltage of each of the memory cells. That is, the threshold voltage of every memory cell is sensed and the sensed threshold voltage is transmitted to the program controller 500. The memory cells are divided into threshold voltage groups G1 to G7 in accordance with their threshold voltage distribution, and a potential range of each memory cell in each group is verified. Here, it is desirable that a threshold voltage distribution width for one group is identical to the step voltage ΔV. To read the threshold voltage distribution of the memory cells, the bit lines BL0 to BLk are precharged to a high level by using the page buffers PB0 to PBk, and then a read voltage corresponding to each of the groups G1 to G7 is applied in sequence to the word line WL. Subsequently, potential change of the bit lines BL0 to BLk is sensed by using the page buffers PB0 to PBk, and the sensed potential change is stored as the threshold voltage distribution value. The threshold voltage distribution value of the sensed memory cells are transmitted to the program controller 500 through the column decoder 300. The program controller 500 divides the threshold voltage distribution value data into the groups G1 to G7, with data having the same threshold voltage distribution value being included in the same group.

Seven groups G1 to G7 exist in the above embodiment, but different number of groups may exist depending on the threshold voltage distribution width.

5) Step S550 of Setting a Target Number by Which a Program Pulse for Each of the Memory Cells is Provided

The program controller 500 sets the target number by which the program pulse for each of the memory cells is provided by using the program data PGM_DATA transmitted in the first program operation S510 and the sensing data Vth_DATA transmitted in the step S540. More particularly, when programming the memory cell included in the seventh group G7 to a first state PV1, the target number is set to 7. The target number is set to 6 when programming the memory cell included in the sixth group G6 to the first state PV1, and is set to 5 when programming the memory cell included in the fifth group G5 to the first state PV1. In other words, when programming to the first state PV1, the target number is changed in sequence by 1 depending on which group G1 to G7 is being programmed. This is because each of the groups G1 to G7 having the threshold voltage distribution width which ideally is identical to the step voltage ΔV shifts into a correct group if the program voltage is increased by the step voltage ΔV.

The target number increases from the preset target number for corresponding group in accordance with program state PV1, PV2 and PV3 to be programmed. For example, the target number increases by 5 in case that the memory cell is to be programmed to the second state PV2, and increases by 10 in case that the memory cell is to be programmed to the third state PV3.

For example, if the memory cell included in the sixth group G6 is to be programmed to the third state PV3, the target number is set to 16 by adding the target number 10 (where the target number 10 is in accordance with the third state PV3 to be programmed) to the target number 6 (where the target number 6 is according to the sixth group G6). For another example, if the memory cell included in the third group G3 is to be programmed to the second state PV2, the target number is set to 8 by adding the target number 5 (where the target number 5 is in accordance with the second state PV2 to be programmed) to the target number 3 (where the target number 3 is according to the third group G3).

6) Second Program Operation S560

Each of the page buffers PB0 to PBk controls potential of the bit line corresponding to the program data to have the supply voltage (where the supply voltage is the program inhibition voltage) or the ground voltage (where the ground voltage is the program allowable voltage) in accordance with the transmitted program data. Subsequently, the program voltage increasing in sequence by the step voltage ΔV is applied to the word line WL shared by the memory cells. In this case, it may be desirable that the initial voltage of the applied program voltage is raised by the step voltage ΔV from the program voltage applied finally in the first program operation S510.

The program pulse counter 400 increases a counting number by 1 whenever the program voltage increases by the step voltage ΔV and outputs a counting signal corresponding to the counting number of the program pulse to the program controller 500. The program controller 500 compares the counting number corresponding to the counting signal with the target number set for each of the memory cells, and outputs control signals SET<k:0> to the page buffers PB0 to PBk in accordance with the comparing result. For example, if a target number of the memory cell corresponding to the page buffer PB0 is set to 10, the program controller 500 compares the counting number corresponding to the counting signal with the set target number and outputs a control signal SET0 in accordance with the comparing result. In other words, if the counting number corresponding to the counting signal is smaller than or identical to the set target number, the page buffer PB0 maintains potential of the bit line BL0 to the program available or permission voltage (ground voltage) in response to the control signal SET0. If, on the other hand, the counting number is higher than the set target number, the page buffer PB0 prevents programming by increasing the potential of the bit line BL0 up to the program inhibition voltage (supply voltage) in response to the control signal SET0.

The above second program operation terminates if the program voltage increased in sequence by the step voltage ΔV increases to a preset ending bias voltage.

As described above, an embodiment of the present invention sets the target number according to the threshold voltage distribution of the memory cells and the state to be programmed, and applies the program voltage increased in sequence by the step voltage ΔV in accordance with the set target number, thereby simultaneously programming the memory cells. As a result, the program verification operation performed whenever the program pulse is provided is skipped, and thus program operation time reduces.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A non-volatile memory device comprising:
a page buffer unit which is connected to bit lines configured to control a potential of the bit lines in response to control signals; and
a program controller configured to perform a comparison of a count of a number of program pulses provided to the memory cells with a target number of program pulses to be provided and output the control signals in accordance with the comparison.

2. The non-volatile memory device of claim 1, wherein the target number is set in accordance with a threshold voltage value of the memory cells and a state to be programmed.

3. The non-volatile memory device of claim 2, wherein the program controller includes:
a program pulse setting unit configured to set the target number in accordance with the threshold voltage value of the memory cells and the state;
a comparing unit configured to compare the target number with the count and output a comparing signal in accordance with the comparison; and
a control signal generator configured to output the control signals in response to the comparing signal.

4. The non-volatile memory device of claim 3, wherein the page buffer unit includes a plurality of page buffers,
wherein each of the page buffers senses a threshold voltage distribution value of a memory cell connected to the bit line, and outputs the sensed threshold voltage distribution value to the program controller.

5. The non-volatile memory device of claim 4, wherein the page buffer unit applies a program inhibition voltage to a corresponding bit line if the count is higher than the target number, and applies a program permission voltage to the corresponding bit line if the count is smaller than or same as the target number.

6. The non-volatile memory device of claim 1, wherein the program controller further comprising a program pulse counter configured to count the number of program pulses provided to the memory cells.

7. A method of programming a non-volatile memory device, the method comprising:
programming memory cells so that at least one of the memory cells has a threshold voltage higher than a preset threshold voltage;
setting a target number by which a program pulse is to be provided to the memory cells by verifying a threshold voltage range of each of the memory cells; and
applying a program permission voltage to a bit line connected to the memory cells if a count of a number of program pulses provided to the memory cells is smaller than or same as the target number.

8. The method of claim 7, further comprising:
programming the memory cells by increasing a program voltage by a step voltage until the count becomes higher than the target number, after the applying the permission voltage to the bit line connected to the memory cells.

9. The method of claim 7, further comprising:
applying a program inhibition voltage to the bit line connected to memory cells if the count is higher than the target number.

10. The method of claim 7, wherein the setting the target number includes:
setting the target number by adding a number of the program pulses according to the threshold voltage range of each of the memory cells to a number by which the program pulse is provided in accordance with a state.

11. The method of claim 7, wherein the verifying the threshold voltage range includes:
sensing a threshold voltage value of each of the memory cells; and
grouping the memory cells into threshold voltage groups in accordance with the sensed threshold voltage value.

12. The method of claim 11, wherein each of the threshold voltage groups has a threshold voltage distribution width corresponding to the step voltage.
programming the memory cells by increasing a program voltage by a step voltage until the count becomes higher than the target number.

13. The method of claim 7, further comprising:
performing a program verification operation after programming the memory cells until the count becomes higher than the target number.

14. A method of programming a non-volatile memory device, the method comprising:
setting a target number by which a program pulse is provided to memory cells according to a target state of each of the memory cells;
providing the increasing program pulse to the memory cells in order, and
applying a program permission voltage to a bit line connected to the memory cells if a count of a number of program pulses provided to the memory cells is smaller than or same as the target number,

15. The method of claim 14, further comprising:
applying an initial program pulse having a potential level lower than the program pulse provided to the memory cells before the setting the target number;
verifying at least one of the memory cells has a threshold voltage higher than a preset threshold voltage; and
grouping the memory cells into threshold voltage groups in accordance with a read threshold voltage distribution by reading a threshold voltage distribution of the memory cells when one or more of the memory cells has threshold voltage higher than the preset threshold voltage.

16. The method of claim 15, wherein the target number is set according to the target state of the memory cells to be programmed and a group in which a corresponding memory cell is included.

17. The method of claim 15, further comprising:
increasing an initial program voltage by a step voltage and performing the applying the initial program pulse if it is verified that the threshold voltage of every memory cell is smaller than the preset threshold voltage.

18. The method of claim 17, wherein each of the threshold groups has a threshold voltage distribution corresponding to the step voltage.

19. The method of claim 14, further comprising;
applying a program inhibition voltage to the bit line connected to the memory cells if the count is higher than the target number.

20. The method of claim 17, wherein the providing the increasing program pulse to the memory cells is performed until the count of the number of program pulses provided to the memory cells becomes higher than the target number.
